(19) United States
(12) Patent Application Publication
(10) Pub. No.: US 2026/0304918 A1
(43) Pub. Date: Oct. 1, 2026

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Shinichi HOSHI, Nisshin-shi (JP)

(21) Appl. No.: 19/411,526

(22) Filed: Dec. 8, 2025

(30) Foreign Application Priority Data
Mar. 31, 2025 (JP) 2025-058682

(51) Int. Cl. H10D 84/80; H10D 30/47; H10D 62/85; H10D 64/23

(52) U.S. Cl. CPC H10D 84/811; H10D 30/475; H10D 62/8503; H10D 64/257

(57) ABSTRACT

A semiconductor device includes a cathode layer and an anode layer arranged in a first direction. The cathode layer is arranged to include a position opposing a drain wiring portion in a stacking direction of a support substrate and a component substrate. The anode layer is arranged to include a position opposing a source wiring portion in the stacking direction. A source through via is arranged to connect the source wiring portion and the anode layer. A drain through via is arranged to connect the drain wiring portion and the cathode layer.

### CROSS REFERENCE TO RELATED APPLICATION

This application is based on Japanese Patent Application No. 2025-058682 filed on Mar. 31, 2025, the disclosure of which is incorporated herein by reference.

### TECHNICAL FIELD

The present disclosure relates to a semiconductor device including a high electron mobility transistor (HEMT).

### BACKGROUND

A semiconductor device has a HEMT formed using a nitride semiconductor layer. However, since the HEMT does not have a parasitic diode formed by an n-type layer and a p-type layer, the semiconductor device in which only the HEMT is formed has a low avalanche resistance.

### SUMMARY

According to one aspect of the present disclosure, a semiconductor device includes:

a support substrate including a silicon layer in which a diode is formed, the silicon layer including a cathode layer of a first conductivity type and an anode layer of a second conductivity type;

a component substrate including a first semiconductor layer disposed on the support substrate and made of a first gallium nitride based semiconductor to define a drift region, and a second semiconductor layer disposed on the first semiconductor layer and made of a second gallium nitride based semiconductor that has a band gap energy larger than that of the first gallium nitride based semiconductor;

a source electrode disposed on the second semiconductor layer and having a source wiring portion extending in a second direction, and a plurality of source comb-teeth electrodes protruding from the source wiring portion in a first direction, wherein the first direction being one direction in a surface direction of the component substrate and intersecting the second direction;

a drain electrode disposed on the second semiconductor layer and having a drain wiring portion extending in the second direction, and a plurality of drain comb-teeth electrodes protruding from the drain wiring portion in the first direction, the drain comb-teeth electrodes and the source comb-teeth electrodes being arranged alternately in the second direction;

a gate electrode having a gate comb-teeth electrode arranged between the source comb-teeth electrode and the drain comb-teeth electrode in the second direction;

a source through via formed in the component substrate and electrically connecting the anode layer and the source electrode; and

a drain through via formed in the component substrate and electrically connecting the cathode layer and the drain electrode.

The cathode layer and the anode layer may be arranged in the first direction. The cathode layer may be located to include a position opposing the drain wiring portion in a stacking direction of the support substrate and the component substrate. The anode layer may be located to include a position opposing the source wiring portion in the stacking direction. The source through via may be arranged to connect the source wiring portion and the anode layer, and the drain through via may be arranged to connect the drain wiring portion and the cathode layer.

### BRIEF DESCRIPTION OF DRAWINGS

FIG. 1 is a plan view of a semiconductor device according to a first embodiment.

FIG. 2 is a cross-sectional view taken along line II-II in FIG. 1.

FIG. 3A is a cross-sectional view taken along line IIIA-IIIA in FIG. 1.

FIG. 3B is a cross-sectional view taken along line IIIB-IIIB in FIG. 1.

FIG. 4 is an enlarged view of a region IV in FIG. 1.

FIG. 5 is a plan view of a support substrate.

FIG. 6 is a diagram for explaining a support wafer for manufacturing a semiconductor device.

FIG. 7 is a cross-sectional view of a semiconductor device according to a second embodiment.

FIG. 8 is a cross-sectional view of a semiconductor device according to a third embodiment.

FIG. 9 is a plan view of a support substrate according to a fourth embodiment.

### DETAILED DESCRIPTION

A semiconductor device has a high electron mobility transistor (HEMT) formed, for example, using a nitride semiconductor layer. However, the HEMT does not have a parasitic diode formed by an n-type layer and a p-type layer. Therefore, a semiconductor device in which only a HEMT is formed has a low avalanche resistance.

Therefore, when a HEMT is formed in a nitride semiconductor layer of a semiconductor device, for example, a semiconductor substrate is formed by stacking a nitride semiconductor layer on a support substrate having a silicon carbide layer, and a diode having a p-type anode layer and an n-type cathode layer is formed in the silicon carbide layer.

Specifically, in this semiconductor device, a gallium nitride (hereinafter also referred to as GaN) layer and an aluminum gallium nitride (hereinafter also referred to as AlGaN) layer are stacked as nitride semiconductor layer, and a two-dimensional electron gas layer is induced adjacent to the GaN layer of the AlGaN/GaN interface. On the nitride semiconductor layer, a first direction is defined in one direction in the surface direction of the semiconductor substrate, and a second direction intersecting the first direction is defined. The source electrode and the drain electrode are arranged in the second direction, with the longitudinal direction along the first direction. The anode layer and the cathode layer formed on the silicon carbide layer are arranged in the second direction so that the anode layer faces the source electrode and the cathode layer faces the drain electrode. The anode layer is connected to the source electrode through a source through-via formed in the nitride semiconductor layer. The cathode layer is connected to the drain electrode through a drain through-via formed in the nitride semiconductor layer.

The present inventor has been studying a semiconductor device, in which the source electrode includes a comb-shaped source electrode and the drain electrode includes a comb-shaped drain electrode, so as to handle larger currents, and the comb-shaped source electrodes and the comb-shaped drain electrodes are arranged alternately in the second direction. In this case, if a diode is formed in the silicon carbide layer as described above, the anode layer is formed at position facing the comb-shaped source electrode and the cathode layer is formed at position facing the comb-shaped drain electrode. That is, the anode layers and the cathode layers are alternately and repeatedly formed in the second direction. The anode layer is connected to the source electrode through a source through-via, and the cathode layer is connected to the drain electrode through a drain through-via.

In such a semiconductor device, the semiconductor device tends to become large and is susceptible to the effects of warping, distortion, etc., since the source electrode includes the comb-shaped source electrode and the drain electrode includes the comb-shaped drain electrode. If misalignment occurs between the source electrode and the anode layer, and between the drain electrode and the anode layer, there may be poor connection or the like. In this case, it is conceivable to deal with the misalignment by increasing the width of the comb-shaped source electrode and the comb-shaped drain electrode in the second direction, but this configuration reduces the area that actually operates as a HEMT.

The present disclosure provides a semiconductor device to restrict the occurrence of connection defects.

According to one aspect of the present disclosure, a semiconductor device has a support substrate including a silicon layer in which a diode is formed. The silicon layer includes a cathode layer of a first conductivity type and an anode layer of a second conductivity type. The semiconductor device has a component substrate including: a first semiconductor layer arranged on the support substrate and made of a first GaN-based semiconductor constituting a drift region; and a second semiconductor layer arranged on the first semiconductor layer and made of a second GaN-based semiconductor having a band gap energy larger than that of the first GaN-based semiconductor. One direction in the surface direction of the component substrate is defined as a first direction, and another direction intersecting the first direction is defined as a second direction. The semiconductor device has a source electrode including: a source wiring portion arranged on the second semiconductor layer and extending in the second direction; and source comb-teeth electrodes protruding in the first direction from the source wiring portion. The semiconductor device has a drain electrode including: a drain wiring portion arranged on the second semiconductor layer and extending in the second direction; and drain comb-teeth electrodes arranged alternately with the source comb-teeth electrodes in the first direction. The semiconductor device has a gate electrode including a gate comb-teeth electrode arranged between the source comb-teeth electrode and the drain comb-teeth electrode in the second direction. A source through-via is formed in the component substrate to electrically connect the anode layer and the source electrode. A drain through-via is formed in the component substrate to electrically connect the cathode layer and the drain electrode. The cathode layer and the anode layer are arranged along the first direction. The cathode layer is arranged to include a position facing the drain wiring portion in a stacking direction of the support substrate and the component substrate. The anode layer is arranged to include a position facing the source wiring portion in the stacking direction. The source through-via is arranged to connect the source wiring portion and the anode layer. The drain through-via is arranged to connect the drain wiring portion and the cathode layer.

According to this, the anode layer and the cathode layer are arranged in the first direction that intersects with the arrangement direction of the source comb-teeth electrodes and the drain comb-teeth electrodes. The through-via for the anode layer is arranged to connect the source wiring portion and the anode layer. The through-via for the cathode layer is arranged to connect the drain wiring portion and the cathode layer. This widens the connectable area of the source electrode and the anode layer connected to the through-via for the anode layer, and widens the connectable area of the drain electrode and cathode layer connected to the through-via for the cathode layer. Therefore, the occurrence of connection failure can be restricted.

Hereinafter, embodiments of the present disclosure will be described with reference to the drawings. In the following embodiments, parts that are identical or equivalent to each other are denoted by the same reference numerals.

### First Embodiment

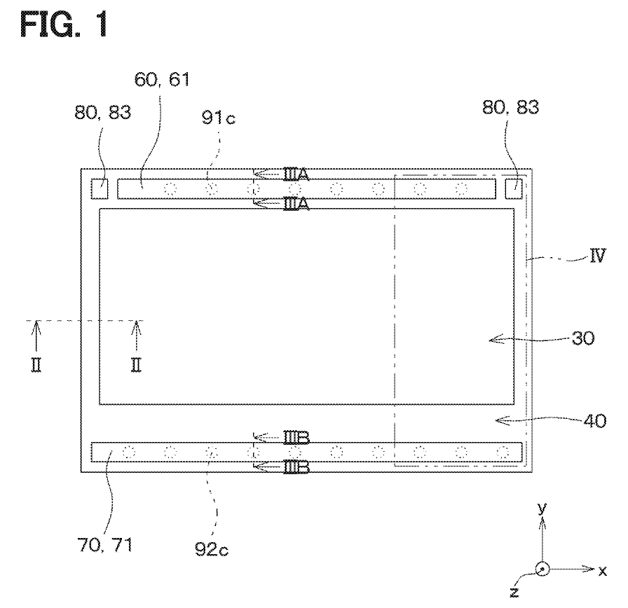

A semiconductor device of a first embodiment will be described with reference to FIGS. 1, 2, 3A, 3B, 4, and 5. In FIG. 1, a source comb electrode 62, a drain comb electrode 72, a gate comb electrode 82, and the like, which will be described later, are omitted.

The semiconductor device of this embodiment includes a semiconductor substrate 1. The semiconductor substrate 1 has a support substrate 10 containing silicon and a component substrate 20 disposed on the support substrate 10. A HEMT is formed in the component substrate 20. The semiconductor substrate 1 has a first surface 1a adjacent to the component substrate 20 and a second surface 1b adjacent to the support substrate 10. In the following description, the thickness (i.e., depth) direction of the semiconductor substrate 1 will be referred to as the z direction. A direction parallel to the first surface 1a of the semiconductor substrate 1 (i.e., a direction perpendicular to the z direction) will be referred to as the x direction. A direction perpendicular to the x direction and the z direction will be referred to as the y direction. The z direction is the normal direction to the first surface 1a of the semiconductor substrate 1 and also the stacking direction of the support substrate 10 and the component substrates 20. The y direction is one direction in the plane direction of the component substrate 20, and can be called the first direction. The x direction can be called the second direction, and the z direction can be called the third direction. The semiconductor substrate 1 of this embodiment is, for example, rectangular in plan view, with a short side length along the y direction being 5 mm, and a long side length along the x direction being 6 mm.

The component substrate 20 has a buffer layer 21, an undoped GaN layer 22, and an undoped AlGaN layer 23 stacked in this order along the z direction. The buffer layer 21, the GaN layer 22, and the AlGaN layer 23 are composed of epitaxial layers epitaxially grown on the support substrate 10.

The buffer layer 21 is made of, for example, an undoped GaN layer. The buffer layer 21 is used to adjust the breakdown voltage of the HEMT, and its thickness is adjusted appropriately depending on the required breakdown voltage.

The GaN layer 22 and the AlGaN layer 23 are stacked in this order to form a heterojunction structure. The semiconductor device of this embodiment uses the GaN layer 22 and the AlGaN layer 23 as channel formation layer, and operates by utilizing a two-dimensional electron gas layer 24 induced by the piezoelectric effect and spontaneous polarization effect on the GaN layer 22 of the AlGaN/GaN interface.

Specifically, the GaN layer 22 is a part of an electron transit layer that operates as a drift region, and corresponds to a first semiconductor layer made of a first GaN-based semiconductor material. The AlGaN layer 23 is a part of an electron supply layer, and corresponds to a second semiconductor layer made of a second GaN-based semiconductor material. The AlGaN layer 23 is made of a GaN-based semiconductor material that has a larger band gap energy than the GaN-based semiconductor material of the GaN layer 22. As such materials, the first semiconductor layer is made of an undoped GaN layer, and the second semiconductor layer is made of an undoped AlGaN layer 23, as described above.

In the semiconductor device of this embodiment, the semiconductor substrate 1 has an active layer region 30 where the two-dimensional electron gas layer 24 is generated in the GaN layer 22. That is, the active layer region 30 is an active region where the HEMT operates. As shown in FIG. 1, the active layer region 30 of this embodiment has a rectangular shape with the x direction as the longitudinal direction.

The semiconductor device of this embodiment has, an element isolation region 40 different from the active layer region 30. The element isolation region 40 of this embodiment is disposed to surround the active layer region 30 and is electrically isolated from the active layer region 30. Specifically, the element isolation region 40 is formed by implanting Ar ions and N ions into the GaN layer 22 and the AlGaN layer 23 disposed in the element isolation region 40 to form an element isolation layer 41. In this embodiment, the element isolation region 40 is thus electrically isolated from the active layer region 30. The element isolation layer 41 is formed deeper than the two-dimensional electron gas layer 24 of the GaN layer 22 so as not to operate as a HEMT.

An interlayer insulating film 50 is formed on the AlGaN layer 23 (i.e., on the first surface 1a of the semiconductor substrate 1). A source electrode 60, a drain electrode 70, and a gate electrode 80 are disposed on the interlayer insulating film 50. The interlayer insulating film 50 is made of, for example, an oxide film.

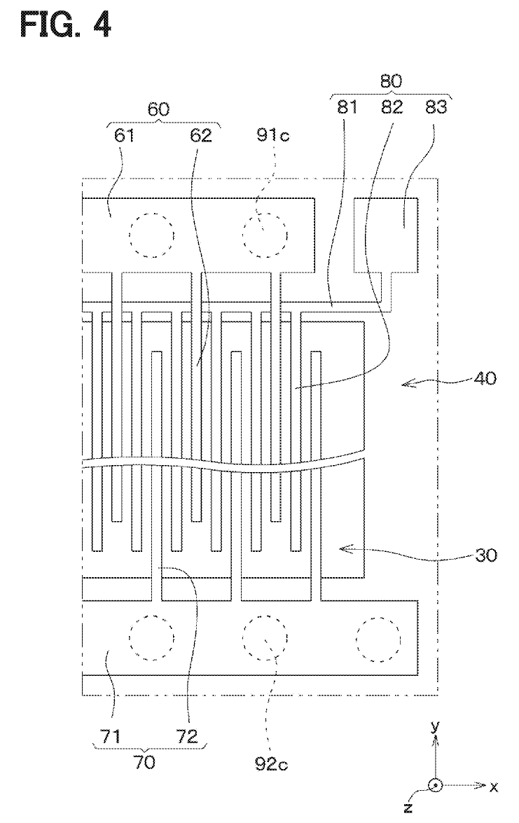

As shown in FIG. 4, the source electrode 60 has a comb-like shape and includes a source wiring portion 61 and a source comb electrode 62. The drain electrode 70 has a comb-like shape and includes a drain wiring portion 71 and a drain comb electrode 72.

Specifically, the source wiring portion 61 of the source electrode 60 and the drain wiring portion 71 of the drain electrode 70 are arranged on the element isolation region 40 to face each other in the y direction across the active layer region 30 and extend in the x direction. The source comb electrode 62 protrudes from the source wiring portion 61 toward the drain wiring portion 71 in the y direction to form a comb-like shape, and has plural electrodes arranged at equal interval in the x direction. The drain comb electrode 72 protrudes from the drain wiring portion 71 toward the source wiring portion 61 in the y direction to form a comb-like shape, and has plural electrodes arranged at equal interval in the x direction. The source comb electrode 62 and the drain comb electrode 72 are disposed on the active layer region 30 so that their comb teeth engage with each other.

Since the source wiring portion 61 is arranged so that each source comb electrode 62 protrudes from one source wiring portion 61, the width of the source wiring portion 61 in the x direction is made sufficiently longer than the width of the source comb electrode 62. Since the drain wiring portion 71 is arranged so that each drain comb electrode 72 protrudes from one drain wiring portion 71, the width of the drain wiring portion 71 in the x direction is made sufficiently longer than the width of the drain comb electrode 72.

The source comb electrode 62 is electrically connected to the AlGaN layer 23 through a contact hole 51 formed in the interlayer insulating film 50. The drain comb electrode 72 is electrically connected to the AlGaN layer 23 through a contact hole 52 formed in the interlayer insulating film 50. Although not particularly limited, the source comb electrode 62 (i.e., the source electrode 60) and the drain comb electrode 72 (i.e., the drain electrode 70) are made of an ohmic metal that is in ohmic contact with the AlGaN layer 23, and are made of, for example, Ti/Al layer.

In this embodiment, a source pad connected to the external circuit is configured as a part of the source wiring portion 61. Similarly, a drain pad connected to an external circuit is configured as a part of the drain wiring portion 71. However, the source pad may be arranged at a different location drawn out from the source wiring portion 61. Similarly, the drain pad may be disposed at a separate location drawn out from the drain wiring portion 71.

The gate electrode 80 includes a gate wiring portion 81, a gate comb electrode 82, and a gate pad 83. In this embodiment, the gate pad 83 is arranged on both ends of the source wiring portion 61 in the x direction. The gate wiring portion 81 is drawn out from the gate pad 83 and is arranged in the element isolation region 40 to extend in the x direction. More specifically, the gate wiring portion 81 is disposed between the source wiring portion 61 and the active layer region 30 when viewed in the z direction. The gate comb electrodes 82 has plural electrodes arranged to form a comb shape and protrude from the gate wiring portion 81 toward the drain wiring portion 71 in the y direction. The gate comb electrode 82 is disposed between the source comb electrode 62 and the drain comb electrode 72.

The gate comb electrode 82 is disposed on the AlGaN layer 23 via the interlayer insulating film 50. The gate comb electrode 82 (that is, the gate electrode 80) is configured as a Schottky electrode made of, for example, Ni. An insulating film is disposed between the gate electrode 80 and the source electrode 60 so that the gate electrode 80 and the source electrode 60 are electrically insulated from each other. The total length of each gate comb electrode 82 in the y direction is changed appropriately depending on the required performance, and is set to, for example, 50 mm or more. When the sum of the lengths of the gate comb electrodes 82 in the y direction is 50 mm or more, the gate comb electrode 82 has for example, 17 electrodes, each with a length of 3 mm in the y direction at the area located above the active layer region 30.

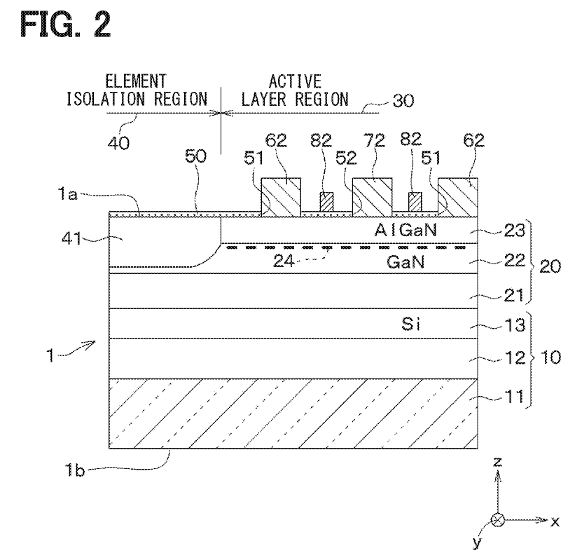

As shown in FIG. 2, the support substrate 10 has a silicon layer 13. In this embodiment, the support substrate 10 is made of a QST (short for Qromis Substrate Technology: registered trademark) substrate. In this embodiment, the support substrate 10 includes a core layer 11, a design layer 12 disposed on the core layer 11, and a silicon layer 13 disposed on the design layer 12.

The core layer 11 causes the thermal expansion coefficient of the support substrate 10 closer to that of GaN, and in this embodiment, is made of AlN (aluminum nitride) or the like, which has a thermal expansion coefficient close to that of GaN. The design layer 12 absorbs irregularities on the surface of the core layer 11 and flattens the surface opposite to the core layer 11, and in this embodiment is made of an oxide film.

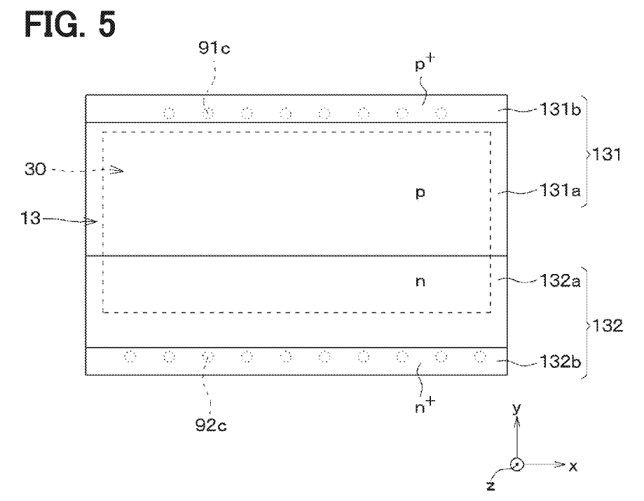

The silicon layer 13 has a main surface (adjacent to the component substrate 20) of Si(111) which is a (111) plane, and a thickness of about 0.3 to 3.0 μm. As shown in FIG. 5, a diode having a p-type anode layer 131 and an n-type cathode layer 132 is formed in the silicon layer 13. Specifically, the anode layer 131 and the cathode layer 132 are arranged in the y direction. That is, the anode layer 131 and the cathode layer 132 are arranged in a direction intersecting the arrangement direction in which the source comb electrode 62 and the drain comb electrode 72 are arranged. In this embodiment, the anode layer 131 and the cathode layer 132 are formed so that both the anode layer 131 and the cathode layer 132 are present in an area facing the active layer region 30 in the z direction. The thickness of the silicon layer 13 is set appropriately depending on the required avalanche operating current.

The anode layer 131 of this embodiment has a p-type anode layer connection layer 131a and an anode layer contact layer 131b having a higher p-type impurity concentration than the anode layer connection layer 131a. The anode layer connection layer 131a is located between the anode layer contact layer 131b and the cathode layer 132. The cathode layer 132 has an n-type cathode layer connection layer 132a and a cathode layer contact layer 132b having a higher n-type impurity concentration than the cathode layer connection layer 132a. The cathode layer connection layer 132a is located between the cathode layer contact layer 132b and the anode layer 131.

Specifically, the anode layer contact layer 131b is formed to extend in the x direction, and includes a portion facing the source wiring portion 61 in the z direction. The cathode layer contact layer 132b is formed to extend in the x direction, and includes a portion facing the drain wiring portion 71 in the z direction.

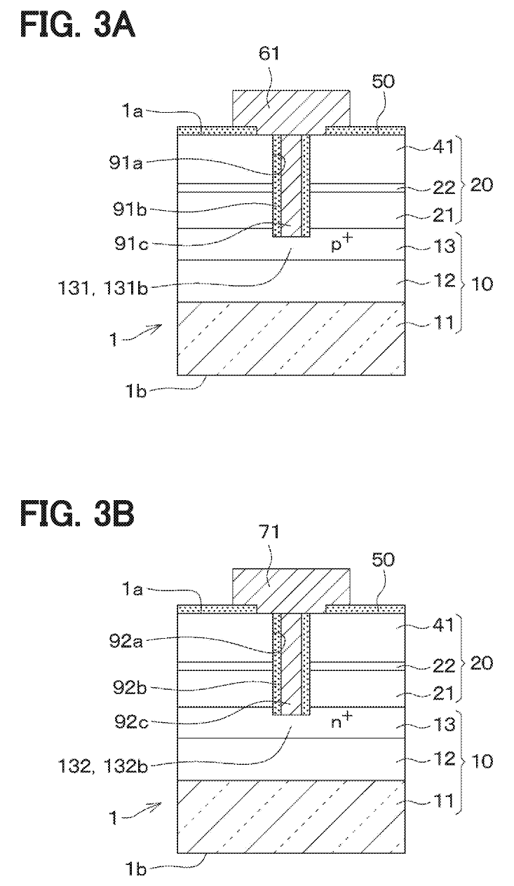

As shown in FIG. 3A, the semiconductor substrate 1 (i.e., the component substrate 20) has an anode layer via hole 91a, to expose the anode layer contact layer 131b, at position overlapping with the source wiring portion 61 in the z direction. In this embodiment, plural anode layer via holes 91a are arranged in the x direction, which is the longitudinal direction of the source wiring portion 61. An insulating film 91b is disposed in the anode layer via hole 91a, and an anode layer through via 91c that connects the source wiring portion 61 and the anode layer contact layer 131b is disposed on the insulating film 91b.

Similarly, as shown in FIG. 3B, a cathode layer via hole 92a exposing the cathode layer contact layer 132b is formed in the semiconductor substrate 1 (i.e., component substrate 20) at position overlapping with the drain wiring portion 71 in the z direction. In this embodiment, plural cathode layer via holes 92a are arranged in the x direction, which is the longitudinal direction of the drain wiring portion 71. An insulating film 92b is disposed in the cathode layer via hole 92a, and a cathode layer through via 92c is disposed on the insulating film 92b to connect the drain wiring portion 71 and the cathode layer contact layer 132b.

The insulating film 91b, 92b is made of an oxide film or the like. The anode layer through via 91c and the cathode layer through via 92c are made of, for example, a Ni silicide layer or a barrier metal containing Ti or the like, with a copper plating film or the like embedded therein. However, the configurations of the anode layer through via 91c and the cathode layer through via 92c can be changed as appropriate. For example, the anode layer through via 91c may be formed by the material of the source wiring portion 61 entering the anode layer via hole 91a. Similarly, the cathode layer through via 92c may be formed by the material of the drain wiring portion 71 entering the cathode layer via hole 92a.

The impurity concentration and the length in the y direction of the anode layer 131 and the cathode layer 132 formed on the silicon layer 13 are adjusted appropriately according to the required avalanche resistance. For example, when avalanche breakdown occurs at 650 V, the anode layer connection layer 131a of the anode layer 131 has a p-type impurity concentration of 1.0×10¹⁶ or more and 1.0×10¹⁸ cm⁻³ or less. In the cathode layer 132, the n-type impurity concentration of the cathode layer connection layer 132a is set to 1.0×10¹⁶ cm⁻³ or less. The anode layer contact layer 131b has a higher p-type impurity concentration than the anode layer connection layer 131a, for example, a p-type impurity concentration of 1.0×10¹⁹ cm⁻³. The cathode layer contact layer 132b has a higher n-type impurity concentration than the cathode layer connection layer 132a, for example, an n-type impurity concentration of 1.0×10¹⁹ cm⁻³. The length of the anode layer 131 in the y direction is, for example, 4000 μm or more, and the length of the cathode layer 132 in the y direction is, for example, 1000 μm or less.

In this embodiment, the n-type corresponds to a first conductivity type, and the p-type corresponds to a second conductivity type. Next, a method for manufacturing the semiconductor device of this embodiment will be described.

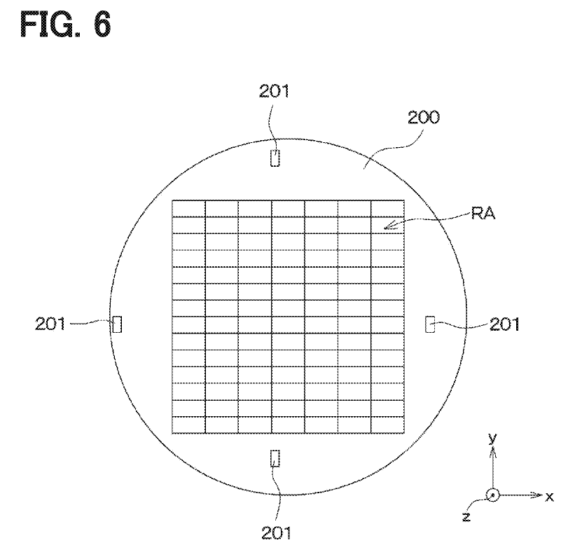

First, as shown in FIG. 6, a support wafer 200 having plural device formation areas RA is prepared. The support wafer 200 is divided into each device formation area RA to form the support substrate 10, in which the core layer 11, the design layer 12, and the silicon layer 13 are stacked. The support wafer 200 has an alignment mark 201 such as a recess on the external side of the device formation area RA. In this embodiment, four alignment marks 201 are formed. The alignment marks 201 are formed so that the intervals between them in the circumferential direction of the support wafer 200 are equal. Although not shown in FIG. 6, dicing lines are set between the device formation areas RA.

Then, by appropriately ion-implanting p-type impurities and n-type impurities into the silicon layer 13 in each device formation area RA of the support wafer 200 using the alignment marks, a diode having an anode layer 131 and a cathode layer 132 is formed. In this embodiment, one anode layer 131 and one cathode layer 132 are formed on the silicon layer 13 in each device formation area RA so that the anode layer 131 and the cathode layer 132 are arranged in the y direction. Therefore, detailed alignment is not required, compared to, for example, a case where plural anode layers 131 and plural cathode layers 132 are alternately formed in the x direction in the silicon layer 13 of each device formation area RA. Therefore, the number of alignment marks 201 formed on the support wafer 200 can be reduced, and the number of device formation areas RA can be increased, thereby improving the yield.

Thereafter, if necessary, the surface of the silicon layer 13 of the support wafer 200 is polished by CMP (abbreviation of Chemical Mechanical Polishing) or the like. When polishing is performed, the thickness of the silicon layer 13 and the depths of the anode layer 131 and the cathode layer 132 formed on the silicon layer 13 are adjusted as appropriate.

Subsequently, although not shown, the buffer layer 21, the GaN layer 22, and the AlGaN layer 23 are epitaxially grown in this order on the support wafer 200. The epitaxial growth is carried out at a temperature of, for example, about 1000 to 1200° C. Furthermore, epitaxial growth may cause warping, thermal distortion, and the like.

Then, a predetermined semiconductor manufacturing process is performed to form the anode layer through via 91c connecting the source wiring portion 61 and the anode layer 131, the cathode layer through via 92c connecting the drain wiring portion 71 and the cathode layer 132, and the like. In addition, the source electrode 60, the drain electrode 70, the gate electrode 80, etc. are formed. Here, a semiconductor device of a comparative example has anode layers 131 and cathode layers 132 arranged alternately in the x direction. In the comparative example, a through via 91c for the anode layer is arranged to connect the source comb electrode 62 and the anode layer 131, and a through via 92c for the cathode layer is arranged to connect the drain comb electrode 72 and the cathode layer 132. When comparing the semiconductor device of this embodiment with the semiconductor device of the comparative example, in the semiconductor device of this embodiment, the connectable area of the source electrode 60 and the anode layer 131 connected to the anode layer through via 91c is wider, and the connectable area of the drain electrode 70 and the cathode layer 132 connected to the cathode layer through via 92c is wider. Therefore, in the semiconductor device of this embodiment, even if warping or thermal distortion occurs, the occurrence of connection defects can be restricted compared to the semiconductor device of the comparative example.

Thereafter, the support wafer 200 is divided into chip units along each device formation area RA, thereby manufacturing the above-mentioned semiconductor devices.

According to the present embodiment, the anode layer 131 and the cathode layer 132 are arranged along the y direction that intersects with the arrangement direction of the source comb electrode 62 and the drain comb electrode 72. The anode layer through via 91c is arranged to connect the source wiring portion 61 and the anode layer 131. The cathode layer through via 92c is arranged to connect the drain wiring portion 71 and the cathode layer 132. Therefore, the connectable area of the source electrode 60 and the anode layer 131 connected to the anode layer through via 91c is widened, and the connectable area of the drain electrode 70 and the cathode layer 132 connected to the cathode layer through via 92c is widened. Therefore, the occurrence of connection failure can be restricted. Furthermore, the semiconductor device of this embodiment has the source comb electrode 62 and the drain comb electrode 72, and therefore can easily accommodate a large current. Furthermore, in the semiconductor device of this embodiment, since the occurrence of connection failures can be restricted, there is no need to increase the width in the x direction of the source comb electrode 62 and the drain comb electrode 72, and the area that actually operates as a HEMT is not reduced.

According to this embodiment, the silicon layer 13 is Si(111), and a QST substrate can be used as the support substrate 10. Therefore, design changes can be reduced, resulting in a semiconductor device with high versatility. Furthermore, although the component substrate 20 is an epitaxial layer, the occurrence of connection defects can be restricted.

### Second Embodiment

A second embodiment will be described. In this embodiment, a GaN thin film substrate is disposed on a silicon layer 13 in comparison with the first embodiment. Other aspects are the same as in the first embodiment, and thus a detailed explanation will be omitted here.

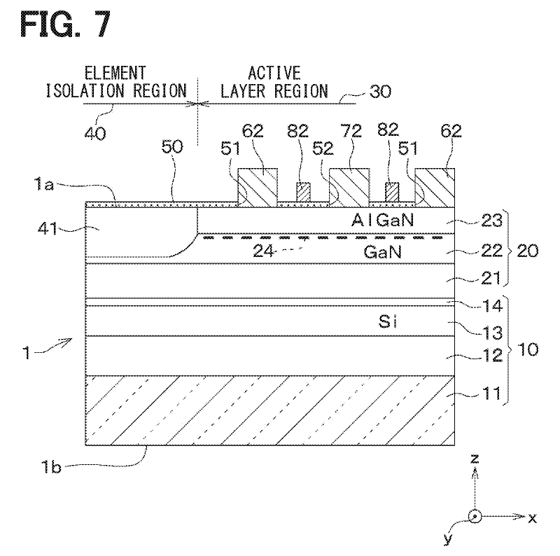

In the semiconductor device of this embodiment, as shown in FIG. 7, the support substrate 10 has the GaN thin film substrate 14 disposed on the silicon layer 13. The silicon layer 13 and the GaN thin film substrate 14 are bonded together by surface activated bonding. The GaN thin film substrate 14 is obtained by cutting a GaN ingot produced by the ammonothermal method, and has a thickness of about 1 to 20 μm.

Although not shown, the anode layer through via 91c is formed to penetrate the GaN thin-film substrate 14 and reach the anode layer 131 of the silicon layer 13. Similarly, the cathode layer through via 92c is formed to penetrate the GaN thin film substrate 14 and reach the cathode layer 132 of the silicon layer 13.

When manufacturing such a semiconductor device, a support wafer 200 is prepared in which the GaN thin film substrate 14 is disposed on the silicon layer 13. Then, an epitaxial layer including GaN is grown on the GaN thin film substrate 14 of the support wafer 200. At this time, since an epitaxial layer containing GaN (that is, the component substrate 20) is grown on the GaN thin film substrate 14, the epitaxial layer is formed by homoepitaxial growth. Therefore, the component substrate 20 has fewer defects, and a HEMT is configured with reduced deterioration in characteristics.

In this embodiment, the component substrate 20 is epitaxially grown on the GaN thin film substrate 14. Therefore, the crystal orientation of the silicon layer 13 can be changed as appropriate.

According to the present embodiment, the anode layer 131 and the cathode layer 132 are arranged in the y direction that intersects with the arrangement direction of the source comb electrode 62 and the drain comb electrode 72. The anode layer through via 91c is arranged to connect the source wiring portion 61 and the anode layer 131. The cathode layer through via 92c is arranged to connect the drain wiring portion 71 and the cathode layer 132. Therefore, effects similar to those of the first embodiment can be obtained.

In this embodiment, the support substrate 10 has the GaN thin film substrate 14 disposed on the silicon layer 13. Therefore, the number of defects that may be contained in the component substrate 20 is reduced, and a HEMT is constructed in which deterioration of characteristics is restricted.

### Third Embodiment

A third embodiment will be described. In this embodiment, a barrier layer is disposed between the GaN thin film substrate 14 and the silicon layer 13 in comparison with the second embodiment. Descriptions of the same configurations and processes as those of the second embodiment will not be repeated hereinafter.

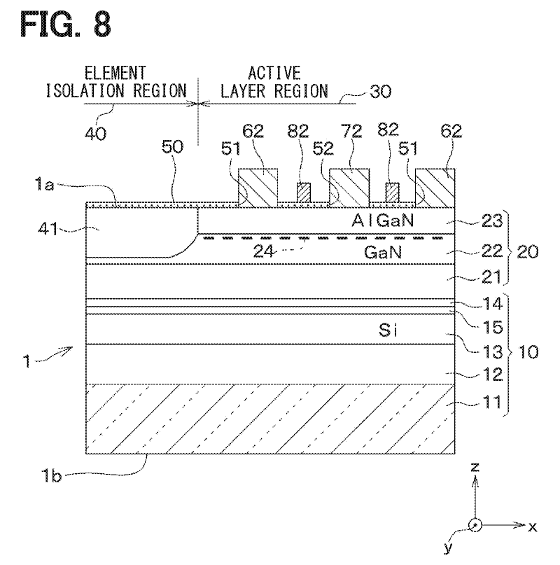

In the semiconductor device of this embodiment, as shown in FIG. 8, the barrier layer 15 is disposed between the GaN thin film substrate 14 and the silicon layer 13. The GaN thin film substrate 14 is bonded to the barrier layer 15 by surface activated bonding.

The barrier layer 15 is provided to prevent Ga in the GaN thin film substrate 14 from reacting with the silicon layer 13 when growing the epitaxial layer (i.e., the component substrate 20), and is made of a material having a melting point of 1500° C or higher. For example, the barrier layer 15 is made of a high melting point metal such as W (tungsten) or Ta (tantalum). The barrier layer 15 is made of a polycrystalline film such as AlN (aluminum nitride) or a single crystal film. The barrier layer 15 is made of a single crystal film such as SiC (silicon carbide) or Al₂O₃ (aluminum oxide). The barrier layer 15 made of such a material is then disposed on the silicon layer 13 by, for example, sputtering. However, the barrier layer 15 is preferably made of a material that has a small difference in thermal expansion coefficient from the GaN thin film substrate 14 and the epitaxial layer (that is, the component substrate 20), and is preferably made of, for example, an AlN single crystal film.

According to the present embodiment, the anode layer 131 and the cathode layer 132 are arranged in the y direction that intersects with the arrangement direction of the source comb electrode 62 and the drain comb electrode 72. The anode layer through via 91c is arranged to connect the source wiring portion 61 and the anode layer 131. The cathode layer through via 92c is arranged to connect the drain wiring portion 71 and the cathode layer 132. Therefore, effects similar to those of the first embodiment can be obtained.

In this embodiment, the barrier layer 15 made of a material having a melting point of 1500° C or higher is disposed between the GaN thin film substrate 14 and the silicon layer 13. This makes it possible to prevent Ga of the GaN thin film substrate 14 from reacting with the silicon layer 13. Therefore, the quality of the epitaxial layer can be prevented from being deteriorated. Furthermore, it is possible to prevent the characteristics of the diode formed in the silicon layer 13 from changing.

### Fourth Embodiment

A fourth embodiment will be described. In this embodiment, the configuration of the diode is changed from that of the first embodiment. Other aspects are the same as in the first embodiment, and thus a detailed explanation will be omitted here.

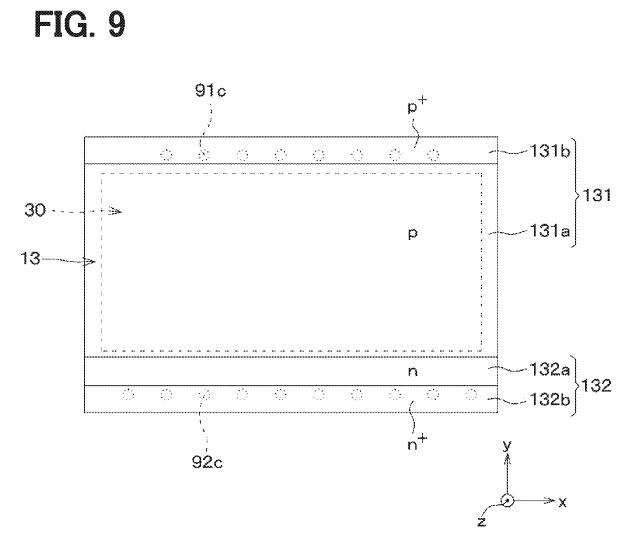

In the semiconductor device of this embodiment, as shown in FIG. 9, the cathode layer 132 is formed only in an area not facing the active layer region 30 in the z direction. That is, the entire portion of the silicon layer 13 that faces the active layer region 30 in the z direction is made into the anode layer 131. In other words, the cathode layer 132 is not formed at the portion of the silicon layer 13 that faces the active layer region 30 in the z direction.

For example, when avalanche breakdown occurs at 650 V, the anode layer 131 has an anode layer connection layer 131a with a p-type impurity concentration of 1.0×10¹⁶ or more and 1.0×10¹⁸ cm⁻³ or less. In the cathode layer 132, the n-type impurity concentration of the cathode layer connection layer 132a is set to 1.0×10¹⁴ cm⁻³ or less. The length of the anode layer 131 in the y direction is, for example, 4800 μm or more, and the length of the cathode layer 132 in the y direction is 200 μm or less.

According to the present embodiment, the anode layer 131 and the cathode layer 132 are arranged in the y direction that intersects with the arrangement direction of the source comb electrode 62 and the drain comb electrode 72. The anode layer through via 91c is arranged to connect the source wiring portion 61 and the anode layer 131. The cathode layer through via 92c is arranged to connect the drain wiring portion 71 and the cathode layer 132. Therefore, effects similar to those of the first embodiment can be obtained.

In this embodiment, the entire portion of the silicon layer 13 that overlaps with the active layer region 30 in the z direction is made into the anode layer 131. In a comparison example of a semiconductor device having a HEMT, a part of the buffer layer 21 opposite the GaN layer 22 is connected to the source electrode 60 in order to reduce current collapse and stabilize the potential to improve the breakdown voltage characteristics. Therefore, as in this embodiment, the current collapse reduction effect and voltage resistance characteristics can be maintained similar to those of the comparison example, and the design can be prevented from becoming complicated by making the portion of the silicon layer 13 that overlaps with the active layer region 30 is made into only the anode layer 131.

### Other Embodiments

Although the present disclosure has been described in accordance with the embodiments, it is understood that the present disclosure is not limited to such embodiments or structures. The present disclosure encompasses various modifications and variations within the scope of equivalents. In addition, various combinations and forms, as well as other combinations or forms including more, less, or only a single element, also fall within the scope and spirit of the present disclosure.

In each of the embodiments, the anode layer through via 91c is arranged in the anode layer via hole 91a via the insulating film 91b, and the cathode layer through via 92c is arranged in the cathode layer via hole 92a via the insulating film 92b. However, in this embodiment, the buffer layer 21, the GaN layer 22, and the AlGaN layer 23 are undoped and are insulating layers. Therefore, the insulating film 91b may not be disposed in the anode layer via hole 91a, and the insulating film 92b may not be disposed in the cathode layer via hole 92a.

Furthermore, the configuration of the support substrate 10 can be changed as appropriate. For example, the support substrate 10 may also have a design layer disposed on the core layer 11 opposite to the design layer 12. Furthermore, the support substrate 10 may be configured to include ScAlMgO₄ (that is, a so-called SAM substrate) instead of AlN.

In addition, the embodiments can be combined as appropriate. For example, the fourth embodiment may be combined with the second or/and third embodiments.

What is claimed is:

1. A semiconductor device comprising:
a support substrate including a silicon layer in which a diode is formed, the silicon layer including a cathode layer of a first conductivity type and an anode layer of a second conductivity type;
a component substrate including
a first semiconductor layer disposed on the support substrate and made of a first gallium nitride based semiconductor to define a drift region, and
a second semiconductor layer disposed on the first semiconductor layer and made of a second gallium nitride based semiconductor that has a band gap energy larger than that of the first gallium nitride based semiconductor;
a source electrode disposed on the second semiconductor layer and having
a source wiring portion extending in a second direction, and
a plurality of source comb-teeth electrodes protruding from the source wiring portion in a first direction, wherein the first direction being one direction in a surface direction of the component substrate and intersecting the second direction;
a drain electrode disposed on the second semiconductor layer and having
a drain wiring portion extending in the second direction, and
a plurality of drain comb-teeth electrodes protruding from the drain wiring portion in the first direction, the drain comb-teeth electrodes and the source comb-teeth electrodes being arranged alternately in the second direction;
a gate electrode having a gate comb-teeth electrode arranged between the source comb-teeth electrode and the drain comb-teeth electrode in the second direction;
a source through via formed in the component substrate and electrically connecting the anode layer and the source electrode; and
a drain through via formed in the component substrate and electrically connecting the cathode layer and the drain electrode, wherein
the cathode layer and the anode layer are arranged in the first direction,
the cathode layer is located to include a position opposing the drain wiring portion in a stacking direction of the support substrate and the component substrate,
the anode layer is located to include a position opposing the source wiring portion in the stacking direction,
the source through via is arranged to connect the source wiring portion and the anode layer, and
the drain through via is arranged to connect the drain wiring portion and the cathode layer.

2. The semiconductor device according to claim 1, wherein
the silicon layer is Si(111), and the component substrate is an epitaxial layer.

3. The semiconductor device according to claim 1, wherein
the component substrate is an epitaxial layer, and
a gallium nitride thin film substrate made of gallium nitride is disposed between the support substrate and the component substrate.

4. The semiconductor device according to claim 3, wherein a barrier layer made of a material having a melting point of 1500°C or higher is disposed between the gallium nitride thin film substrate and the component substrate.

5. The semiconductor device according to claim 1, wherein
the component substrate has an active layer region through which a current flows and an element isolation region different from the active layer region, and
a portion of the silicon layer opposing the active layer region in the stacking direction is entirely made into the anode layer.
